(19) United States
(12) Patent Application Publication
(10) Pub. No.: US 2010/0147368 A1
(43) Pub. Date: Jun. 17, 2010

(54) PHOTOVOLTAIC CELL WITH SHALLOW EMITTER

(75) Inventor: Leonid Borishovich Rubin, Burnaby (CA)

Correspondence Address: KNOBBE MARTENS OLSON & BEAR LLP, 2040 MAIN STREET, FOURTEENTH FLOOR, IRVINE, CA, 92614, US

(73) Assignee: DAY4 ENERGY INC., Burnaby, British Columbia (CA)

(21) Appl. No.: 12/600,653

(22) PCT Filed: Feb. 22, 2008
(86) PCT No.: PCT/CA08/00349

§ 371 Date: Feb. 3, 2010

Related U.S. Application Data
(63) Continuation-in-part of application No. 11/751,524, filed on May 21, 2007.

(30) Foreign Application Priority Data
May 17, 2007 (TW) 96117614

(51) Int. Cl. H01L 31/00; H01L 31/18

(52) U.S. Cl. 136/255; 136/256; 438/72; 257/E31.119

(57) ABSTRACT

A photovoltaic semiconductor apparatus for use in forming a solar cell with shallow emitter is disclosed The apparatus includes first and second adjacent oppositely doped volumes of semiconductor material forming a semiconductor heterojunction The apparatus also includes a first passivation layer of material on the front side, the first passivation layer having a first outer surface and a plurality of openings therethrough defining corresponding unpassivated areas of the front side that are unpassivated by the first passivation layer The apparatus further includes a first conductive anti-reflective coacting on the first outer surface of the passivation layer and on the corresponding unpassivated areas of the front side The apparatus may further include dielectric antireflective coating on an outer surface of the first passivation layer.

### RELATED APPLICATION

The U.S. designation of the present application is a continuation-in-part of U.S. application Ser. No. 11/751,524, filed May 21, 2007.

### BACKGROUND OF THE INVENTION

1. Field of Invention The present invention generally relates to semiconductor devices and more particularly to highly efficient photovoltaic (PV) cells with shallow emitters.

2. Description of Related Art

Crystalline silicon photovoltaic (PV) cells are generally produced from a silicon substrate doped with impurities to produce a p/n heterojunction. The p/n heterojunction may be produced by diffusion of either phosphorus or boron typically into the front side of a p-type or n-type semiconductor substrate. Fixed charges at the heterojunction, due to the boron and phosphorous atoms create a permanent dipole charge layer with a high electric field. A portion of the PV cell, between the front side and the p/n heterojunction is referred to as an emitter. When the PV cell is illuminated by light, photons of light energy produce electron-hole pairs and the high electric field of the p/n heterojunction provides charge separation. This displacement of free charges results in a voltage difference between the p and n regions of the substrate. When the p and n regions are connected to an electric circuit, an electric current flows. This electric current is collected from the PV cell by front and back side metal contacts.

Front and back side metal contacts are typically provided on the substrate through the use of screen printing technology in which a partially electrically conductive paste, which typically contains silver and/or aluminum is screen printed through a mask onto front and back surfaces of the substrate.

For the front side of the substrate, the mask typically has openings through which the conductive paste contacts the substrate surface. The front side mask is typically configured to produce a plurality of thin parallel line contacts connected to two or more thicker lines that are connected to, and extend generally perpendicular to the parallel line contacts. After spreading paste on the mask, the mask is removed and the wafer bearing the partially conductive paste is heated to dry the paste. The wafer is then “fired” in an oven and the paste enters a metallic phase, where at least part of it diffuses through the front surface of the substrate and into the substrate structure while a portion is left solidified on the front surface. The multiple thin parallel lines form thin parallel linear current collecting areas referred to as “fingers”, intersected by thicker perpendicular lines referred to as “bus bars”. The fingers collect the electrical current from the front side of the substrate and transfer it to the bus-bars. The bus bars can be connected to an electrical circuit.

Typically, the width and the height of each finger are approximately 120 microns and 10 microns respectively. While the fingers are sufficient to collect small electric currents from the substrate, the bus-bars are required to collect a much greater current from the plurality of fingers and therefore have correspondingly larger cross section and width.

On the back surface of the substrate, a partially conductive paste containing a composition of silver and aluminum is screen printed and dried in areas that are to act as electrical contacts. A partially conductive paste containing aluminum is then spread over the entire back surface of the substrate and partially overlaps edges of the above-mentioned contacts. This paste is then dried by heating. Then the substrate is subjected to “firing” in an oven, and part of the aluminum diffuses into the back surface of the substrate. This produces a highly doped p+ layer, or back surface field (BSF) at the back surface of the substrate. The aluminum also alloys with the silver/aluminum contacts in areas in which it overlaps the contacts. The silver/aluminum contacts thus appear as silver/aluminum pads among the back surface field of aluminum that is diffused into the back surface of the substrate. The silver/aluminum contacts collect electrical current from the rear side of substrate and act as electrical terminals for the back side of the substrate.

The area that is occupied by the fingers and bus bars on the front side of the substrate is known as the shading area because the non-transparent paste that forms the fingers and bus bars prevents solar radiation from reaching the surface of the substrate in this area. This shading area reduces the current producing capacity of the device. Modern solar cell substrate shading occupies 6-10% of the available active surface area. The presence of metal contacts on the front side and the silver/aluminum pads on the back side also results in a decrease of voltage generated by the substrate in proportion to the metallized area because diffusion of the contact paste into the front surface of the substrate has a detrimental effect on charge recombination. Conventional metallization techniques may also cause bowing of the substrate due to the difference in thermal expansion coefficients between silicon and silver/aluminum pastes. This can be a problem in thin solar cells, which may employ substrates less than 180 microns thick, making such cells fragile thus reducing production yield.

In addition conventional metallization techniques result in substantial losses in the emitter region. Therefore in order to increase conversion efficiency of solar cells that employ conventional screen printed metallization, emitter design parameters are often optimized in such a way that in light-illuminated areas doping concentration levels are as low as possible and the emitter is very thin. This provides for improved photon collection, especially in the blue spectral region. Doping concentrations and emitter thickness in areas under current collecting fingers and bus bars are usually substantially higher to provide for low resistance electric contact between the substrate and the fingers and bus bars without shunting the p/n heterojunction. In other words it has been desirable to make solar cells with a selective emitter that contains areas with different dopant concentration and different emitter thicknesses. Although the use of a selective emitter has proved to be effective in improving PV solar cell efficiency, implementation of a selective emitter in practice, is quite complicated.

U.S. Pat. No. 5,871,591 entitled Silicon Solar Cells made by a Self-Aligned, Selective-Emitter, Plasma-Etchback Process, to Ruby et al describes a process for forming and passivating a selective emitter. The process uses a plasma etch of a heavily doped emitter to improve its performance. The screen printed metallic patterns, so called grids of the solar cell, are used to mask the plasma etch so that only the emitter in the region between the grids is etched, while the region beneath the grids remains heavily doped to provide low contact resistance between the substrate and the screen printed metallic grids. This process is potentially low-cost because it does not require precision alignment between heavily doped regions and screen printed patterns. After the emitter is etched, silicon nitride is deposited by plasma-enhanced chemical vapor deposition, thereby creating an antireflection coating. The solar cell is then annealed in a forming gas. While this method allows fabricating a selective emitter and increased solar cell efficiency, it has a disadvantage in that selective emitter formation happens only after screen printed metallic patterns have been formed on the solar cell and thus is dependent on conventional screen printing metallization techniques.

U.S. Pat. No. 6,091,021 entitled “Silicon Solar Cells made by a Self-Aligned, Selective-Emitter, Plasma-Etchback Process” to Ruby et al describes photovoltaic cells and a method for making them wherein metalized grids of the cells are used to mask portions of cell emitter regions to allow selective etching of phosphorous-doped emitter regions. This self-aligned selective etching allows for enhanced blue response as compared to cells with uniform heavy doping of the emitter, while preserving heavier doping in the region beneath the gridlines needed for low contact resistance. This may replace expensive and difficult alignment methodologies used to obtain selectively etched emitters, and may be easily integrated with existing plasma processing methods and techniques. However, the proposed method requires that selective emitter formation be done only after screen printed metallization has been applied on the solar cell, making the process dependent on conventional screen printed metallization techniques.

U.S. Pat. Nos. 6,552,414 and 6,825,104 both entitled “Semiconductor Device with Selectively Diffused Regions” to Horzel et al. describe a PV cell having two selectively diffused regions with different doping levels. A first screen printing process is used to deposit a paste containing dopant on diffusion regions of a substrate to produce highly doped emitter regions. A second screen printing deposition of a metallization pattern is precisely aligned to ensure that a connection is made to the highly doped emitter regions. Again screen printing metallization techniques are required.

### SUMMARY OF THE INVENTION

In accordance with one aspect of the invention, there is provided a photovoltaic semiconductor apparatus for use in forming a solar cell. The apparatus includes first and second adjacent oppositely doped volumes of semiconductor material forming a semiconductor heterojunction. The first doped volume acts as an emitter and has a front side for receiving light. The apparatus also includes a first passivation layer of material on the front side, the first passivation layer having a first outer surface and a plurality of openings therethrough defining corresponding unpassivated areas of the front side that are unpassivated by the first passivation layer. The apparatus further includes a first conductive anti-reflective coating on the first outer surface of the passivation layer and on the corresponding unpassivated areas of the front side.

The semiconductor heterojunction may be at least one of an ion-implanted heterojunction and a thermally diffused heterojunction.

The first doped volume may have a sheet resistivity of about 60 ohms per square to about 150 ohms per square and desirably has a sheet resistivity of about 80 ohms per square to about 150 ohms per square.

The first passivation layer may be comprised of at least one of SiO₂, SiN₄ and SiC.

The first passivation layer may have a thickness of about 10 nm to about 500 nm and preferably has a thickness of about 10 nm to about 50 nm.

The openings may have a width of about 50 micrometers to about 200 micrometers.

The openings in the first passivation layer may be arranged in parallel lines across the first outer surface.

The distance between parallel lines of openings in the second passivation layer may be about 500 micrometers to about 5000 micrometers.

The parallel lines may be connected by cross parallel lines to form a grid arrangement.

The grid arrangement may have meshes approximately about 500 micrometers to about 5000 micrometers square.

The first conductive anti-reflective coating may be continuous.

The first conductive anti-reflective coating may have a thickness of about 70 to about 280 nm.

The first conductive anti-reflective coating may be comprised of at least one of: InOx, SnOx, InSnOx, TiOx and ZnOx.

The first conductive anti-reflective coating may have a sheet resistivity of about 1 Ohm/sq. to about 30 Ohm/sq.

The apparatus may include a second passivation layer on the back side surface, the second passivation layer having a second outer surface having a second plurality of openings therethrough defining corresponding unpassivated areas of the second outer surface that are unpassivated by the second passivation layer.

The apparatus may also include a second conductive anti-reflective coating on the second outer surface of the second passivation layer and on the corresponding unpassivated areas of the second outer surface.

The second passivation layer may be comprised of at least one of SiO₂, SiN₄ and SiC.

The second passivation layer may have a thickness of about 10 nm to about 500 nm and preferably has a thickness of about 10 nm to about 50 nm.

The openings in the second passivation layer may have a width of about 50 micrometers to about 200 micrometers.

The openings in the second passivation layer may be arranged in parallel lines across the second outer surface.

The parallel lines may be spaced apart by about 500 micrometers to about 5000 micrometers.

The parallel lines may be connected by cross parallel lines to form a grid arrangement.

The grid arrangement may have meshes about 500 micrometers to about 5000 micrometers square.

The second conductive anti-reflective coating may be continuous.

The second conductive anti-reflective coating may have a thickness that is about at least as thick as the first conductive anti-reflective coating.

The second conductive anti-reflective coating may have a thickness of about 70 to about 500 nm.

The second conductive anti-reflective coating may be comprised of at least one of: InOx, SnOx, InSnOx, TiOx and ZnOx.

The second conductive anti-reflective coating may have a sheet resistivity of about 1 Ohm/sq. to about 30 Ohm/sq.

To employ the photovoltaic semiconductor apparatus in a solar cell, first and second electrodes are connected to the front and back sides of the apparatus. The first electrode includes a first optically transparent electrically insulating film having first and second opposite sides. The first side has a first adhesive for adhering the first film to the first conductive anti-reflective coating. The first electrode further includes a first plurality of conductors embedded in the first adhesive coating such that portions of the first plurality of conductors protrude from the first adhesive. The portions are soldered to the first conductive anti-reflective coating by an alloy coating on the portions to form ohmic connections between the first conductive anti-reflective coating and the portions of the first plurality of conductors such that electrons can pass between the unpassivated areas of the front side and the first plurality of conductors to permit an electric current generated by the photovoltaic semiconductor apparatus to be conducted by the first plurality of conductors.

The second electrode includes a second electrically insulating film having first and second opposite sides. The first side of the second film has a second adhesive for adhering the second film to the second conductive anti-reflective coating. The second electrode further includes a second plurality of conductors embedded in the second adhesive coating such that portions of the second plurality of conductors protrude from the second adhesive. The portions of the second plurality of conductors are soldered to the second conductive anti-reflective coating by an alloy coating on the portions to form ohmic connections between the portions of the second plurality of conductors and the second conductive anti-reflective coating such that electrons can pass between the unpassivated areas of the second outer surface and the second plurality of conductors to permit the electric current generated by the photovoltaic semiconductor apparatus to be conducted by the second plurality of conductors.

Instead of the second passivation layer and the second conductive anti-reflective coating, the apparatus may include a third doped volume adjacent the second doped volume on a side of the second doped volume opposite the semiconductor hetrojunction. The third doped volume has the same doping polarity as the second doped volume thereby forming an isotype junction with the second doped volume. The third doped volume also has a doping concentration greater than a doping concentration of the second doped volume and the third doped volume has a back side surface.

The apparatus may further include a second conductive anti-reflective coating on the back side surface of the third doped volume.

The second conductive anti-reflective coating may be continuous and uniform and may have a thickness that is about the same as, or greater than, a thickness of the first conductive anti-reflective coating.

The second conductive anti-reflective coating may have a thickness of about 70 to about 500 nm.

The second conductive anti-reflective coating may be comprised of at least one of: InOx, SnOx, InSnOx, TiOx and ZnOx.

The second conductive anti-reflective coating may have a sheet resistivity of about 1 Ohm/sq. to about 30 Ohm/sq.

A solar cell employing the apparatus with the third doped volume is formed by connecting first and second electrodes to the front and back surfaces of the apparatus.

The first electrode includes a first optically transparent electrically insulating film having first and second opposite sides. The first side has a first adhesive for adhering the first film to the first conductive anti-reflective coating. The first electrode further includes a first plurality of conductors embedded in the first adhesive such that portions of the first plurality of conductors protrude from the first adhesive coating. The portions are soldered to the first conductive anti-reflective coating by an alloy coating on the portions to form ohmic connections between the first conductive anti-reflective coating and the portions of the first plurality of conductors such that electrons can pass between the unpassivated areas of the front side and the first plurality of Conductors to permit an electric current generated by the photovoltaic semiconductor apparatus to be conducted by the first plurality of conductors.

The second electrode includes a second electrically insulating film having first and second opposite sides. The first side of the second film has a second adhesive for adhering the second film to the second conductive anti-reflective coating. The second electrode further includes a second plurality of conductors embedded in the second adhesive such that portions of the second plurality of conductors protrude from the second adhesive coating. The portions of the second plurality of conductors are soldered to the second conductive anti-reflective coating by an alloy coating on the portions to form ohmic connections between the portions of the second plurality of conductors and the second conductive anti-reflective coating such that electrons can pass between the back side surface of the third volume and the second plurality of conductors to permit the electric current generated by the photovoltaic semiconductor apparatus to be conducted by the second plurality of conductors.

In another embodiment, the second doped volume may have a back side surface and may include a second passivation layer on the back side surface and may further include a layer of aluminum on the second passivation layer. The layer of aluminum has a plurality of laser-fired current collecting contacts extending through the second passivation layer to the second doped volume.

A solar cell employing the apparatus with the layer of aluminum includes first and second electrodes connected to the front and back surfaces of the apparatus respectively. The first electrode includes a first optically transparent electrically insulating film having first and second opposite sides. The first side has a first adhesive for adhering the first film to the first conductive anti-reflective coating. The first electrode further includes a first plurality of conductors embedded in the first adhesive such that portions of the first plurality of conductors protrude from the first adhesive coating. The portions are soldered to the first conductive anti-reflective coating by an alloy coating on the portions to form ohmic connections between the conductive anti-reflective coating and the portions of the first plurality of conductors such that electrons can pass between the unpassivated areas of the front side and the first plurality of conductors to permit an electric current generated by the photovoltaic semiconductor apparatus to be conducted by the first plurality of conductors.

The second electrode includes a second electrically insulating film having first and second opposite sides. The first side of the second film has a second adhesive for adhering the second film to layer of aluminum. The second electrode further includes a second plurality of conductors embedded in the second adhesive such that portions of the second plurality of conductors protrude from the second adhesive coating. The portions of the second plurality of conductors are soldered to the aluminum layer by an alloy coating on the portions to form ohmic connections between the portions of the second plurality of conductors and the aluminum layer to permit the electric current generated by the photovoltaic semiconductor apparatus to be conducted by the second plurality of conductors through the aluminum layer and the laser-fired contacts to the second doped volume.

In accordance with another aspect of the invention, there is provided a method of making a photovoltaic semiconductor apparatus for use in forming a solar cell. The method involves forming a first plurality of openings in a first passivation layer on a front side of a first doped volume of semiconductor material of a semiconductor wafer having first and second adjacent oppositely doped volumes of semiconductor material forming a heterojunction, the first plurality of openings defining corresponding unpassivated areas of the first front side that are unpassivated by the first passivation layer. The method also involves forming a first conductive anti-reflective coating on a first outer surface of the first passivation layer and on the corresponding unpassivated areas of the front side.

Forming the first plurality of openings may involve causing each opening of the first plurality of openings to have a width of about 50 micrometers to about 200 micrometers.

Forming the first plurality of openings in the first passivation layer may involve arranging the first plurality of openings in parallel lines across the first outer surface.

The distance between parallel lines of openings in the first passivation layer may be about 500 micrometers to about 5000 micrometers.

Forming the first plurality of openings in the first passivation layer may involve arranging the first plurality of openings in parallel lines connected by cross parallel lines to form a grid arrangement.

The grid arrangement may have meshes of about 500 micrometers to about 5000 micrometers square.

Forming the first conductive anti-reflective coating may involve forming a first continuous conductive anti-reflective coating on the first outer surface and on the unpassivated areas of the front side surface.

Forming the first conductive anti-reflective conductive coating may involve causing the first conductive anti-reflective coating to have a thickness of about 70 nm to about 280 nm.

Forming the first conductive anti-reflective coating on the first outer surface and on the unpassivated areas of the front side surface may involve applying a material including at least one of InOx; SnOx, InSnOx; TiOx; and ZnOx.

Forming the first conductive anti-reflective coating may involve causing the first conductive anti-reflective coating to have a sheet resistivity of about 1 Ohm/Sq to about 30 Ohm/Sq.

The method may involve forming the heterojunction by at least one of ion-implanting and thermal diffusion.

The method may involve forming the first doped volume to have a sheet resistivity of about 60 ohms per square to about 150 ohms per square and desirably has a sheet resistivity of about 80 ohms per square to about 150 ohms per square

The method may involve forming the first passivation layer.

Forming the first passivation layer may involve forming a layer of at least one of SiO₂, SiN₄ and SiC on the front side.

Forming the first passivation layer may involve causing the first passivation layer to have a thickness of about 10 nm to about 500 nm and desirably about 10 nm to about 50 nm.

The method may involve forming a second plurality of openings in a second passivation layer on a back side surface of the second doped volume of the semiconductor material, the second plurality of openings defining corresponding unpassivated areas on the back side surface. The method may also involve forming a second conductive anti-reflective coating on an outer surface of the second passivation layer and on the unpassivated areas of the second back side surface.

Forming the second plurality of openings may involve causing each of the second plurality of openings to have a width of about 50 micrometers to about 200 micrometers.

Forming the second plurality of openings in the second passivation layer may involve arranging the second plurality of openings in parallel lines across the back side surface.

The distance between said parallel lines in the second passivation layer may be about 500 micrometers to about 5000 micrometers.

Forming the second plurality of openings in the second passivation layer may involve arranging the second plurality of openings in parallel lines connected by cross parallel lines to form a grid arrangement.

The grid arrangement may have meshes of about 500 micrometers to about 5000 micrometers square.

Forming the second conductive anti-reflective coating may involve forming a second continuous conductive anti-reflective coating on the outer surface of the second passivation layer and on the unpassivated areas of the back side surface.

Forming the second conductive anti-reflective conductive coating may involve causing the coating to have a thickness of about 70 nm to about 500 nm.

Forming the second conductive anti-reflective coating may involve coating the outer surface of the second passivation layer and the unpassivated areas of the back side surface with a material including at least one of InOx; SnOx, InSnOx; TiOx; and ZnOx.

Forming the second conductive anti-reflective coating may involve causing the second conductive anti-reflective coating to have a sheet resistivity of about 1 Ohm/Sq to about 30 Ohm/Sq.

The method may involve forming the second passivation layer.

Forming the second passivation layer may involve forming a layer of at least one of SiO₂, SiN₄ and SiC on the outer surface.

Forming the second passivation layer may involve causing the second passivation layer to have a thickness of about 10 nm to about 500 nm and desirably about 10 nm to about 50 nm.

The method may involve adhering an adhesive on an optically transparent electrically insulating film to the first conductive anti-reflective coating such that portions of an alloy coating on corresponding exposed portions of a first plurality of conductors embedded in the adhesive are disposed on the first conductive anti-reflective coating. The method may also involve heating the alloy coating while pressing the exposed portions against the first conductive anti-reflective coating to cause the alloy coating to solder the exposed portions of the first plurality of conductors to the first conductive anti-reflective coating to create ohmic connections between the first plurality of conductors and the first conductive anti-reflective coating.

The method may involve adhering a second adhesive on a second electrically insulating film to the second conductive anti-reflective coating such that portions of a second alloy coating on corresponding exposed portions of a second plurality of conductors embedded in the second adhesive are disposed on the second anti-reflective conductive coating. The method may further involve heating the second alloy coating while pressing the exposed portions of the second plurality of conductors against the second conductive anti-reflective coating to cause the second alloy coating to solder the exposed portions of the second plurality of conductors to the second conductive anti-reflective coating to create ohmic connections between the second plurality of conductors and the second conductive anti-reflective coating.

The method may involve forming a second conductive anti-reflective coating on a back side surface of a third doped volume on a side of the second doped volume opposite the semiconductor junction, the third doped volume having the same doping polarity as the second volume thereby forming an isotype junction and wherein the third doped volume has a doping concentration greater than a doping concentration of the second volume.

Forming the second conductive anti-reflective coating may involve forming a second continuous conductive anti-reflective coating on the back side surface of the third doped volume.

Forming the second conductive anti-reflective coating may involve causing the second conductive anti-reflective coating to have a thickness of about 70 nm to about 500 nm.

Forming the second conductive anti-reflective coating may involve coating the back side surface of the third doped volume with a material including at least one of InOx; SnOx, InSnOx; TiOx; and ZnOx.

Forming the second conductive anti-reflective coating may involve causing the second conductive anti-reflective coating to have a sheet resistivity of about 1 Ohm/Sq to about 30 Ohm/Sq.

The method may involve adhering an adhesive on an optically transparent electrically insulating film to the first conductive anti-reflective coating such that portions of an alloy coating on corresponding exposed portions of a first plurality of conductors embedded in the adhesive are disposed on the first conductive anti-reflective coating. The method may further involve heating the alloy coating while pressing the exposed portions against the first conductive anti-reflective coating to cause the alloy coating to solder the exposed portions of the first plurality of conductors to the conductive anti-reflective coating to create ohmic connections between the first plurality of conductors and the first conductive anti-reflective coating.

The method may involve adhering a second adhesive on a second electrically insulating film to the second conductive anti-reflective coating such that portions of a second alloy coating on corresponding exposed portions of a second plurality of conductors embedded in the second adhesive are disposed on the second conductive anti-reflective coating. The method may further involve heating the second alloy coating while pressing the exposed portions of the second plurality of conductors against the second conductive anti-reflective coating to cause the second alloy coating to solder the exposed portions of the second plurality of conductors to the second conductive anti-reflective coating to create ohmic connections between the second plurality of conductors and the second conductive anti-reflective coating.

The method may involve forming a second passivation layer on a back side surface of the second volume.

Forming the second passivation layer may involve forming a layer of at least one of SiO₂, SiN₄ and SiC on the outer surface.

Forming the second passivation layer may involve causing the second passivation layer to have a thickness of about 10 nm to about 500 nm and desirably about 10 nm to about 50 nm.

The method may involve forming a layer of aluminum on the second passivation layer.

Forming the layer of aluminum may involve forming the layer of aluminum by at least one of vapor deposition and sputtering.

Forming the layer of aluminum may involve forming the layer of aluminum such that the layer of aluminum has a thickness of about 1 micrometer to about 20 micrometers and desirably about 2 micrometers to about 10 micrometers.

The method may involve forming a plurality of laser-fired contacts in the layer of aluminum.

The method may involve adhering an adhesive on an optically transparent electrically insulating film to the first conductive anti-reflective coating such that portions of an alloy coating on corresponding exposed portions of a first plurality of conductors embedded in the adhesive are disposed on the front side. The method may further involve heating the alloy coating while pressing the exposed portions against the first conductive anti-reflective coating on the unpassivated areas to cause the alloy coating to solder the exposed portions of the first plurality of conductors to the conductive anti-reflective coating to create ohmic connections between the first plurality of conductors and the first conductive anti-reflective coating.

The method may involve adhering a second adhesive on a second electrically insulating film to the layer of aluminum such that a second alloy coating on corresponding exposed portions of a second plurality of conductors embedded in the second adhesive are disposed on the layer of aluminum. The method may further involve heating the second alloy coating while pressing the exposed portions of the second plurality of conductors against the aluminum layer to cause the second alloy coating to solder the exposed portions of the second plurality of conductors to the layer of aluminum to create ohmic connections between the second plurality of conductors and the layer of aluminum to permit current to flow between the second plurality of conductors and the second doped volume through the laser-fired contacts and the layer of aluminum.

In accordance with another aspect of the invention, there is provided a photovoltaic semiconductor apparatus for use in forming a solar cell. The apparatus includes first and second adjacent oppositely doped volumes of semiconductor material forming a semiconductor heterojunction, the first doped volume acting as an emitter having a front side for receiving light. The apparatus also includes a first passivation layer of material on the front side, the first passivation layer having a first outer surface and a plurality of openings therethrough defining corresponding unpassivated areas of the front side that are unpassivated by the first passivation layer. The apparatus further includes a dielectric anti-reflective coating on the first outer surface of the passivation layer such that the openings in the passivation layer are void of the dielectric anti-reflective coating. The apparatus also includes a first conductive anti-reflective coating on the first dielectric anti-reflective coating and on the corresponding unpassivated areas of the front side.

The semiconductor heterojunction may include at least one of an ion-implanted heterojunction and a thermally diffused heterojunction.

The first doped volume may include a sheet resistivity of about 60 ohms per square to about 150 ohms per square.

The first doped volume may include a sheet resistivity of about 80 ohms per square to about 150 ohms per square.

The first passivation layer may include at least one of SiO₂, SiN₄ and SiC.

The first passivation layer may have a thickness of about 10 nm to about 200 nm.

The first passivation layer may have a thickness of about 10 nm to about 50 nm.

The openings in the first passivation layer may have a width of about 50 micrometers to about 200 micrometers.

The openings in the first passivation layer may have an elongate shape having a length of between about 0.5 mm and about 4 mm and a width of between about 0.1 mm and about 1 mm. These openings may be spaced apart by about 1 mm to about 6 mm

The openings in the first passivation layer may be arranged in parallel lines across the first outer surface.

The parallel lines may be spaced apart by about 500 micrometers to about 5000 micrometers.

The parallel lines may be connected by cross parallel lines to form a grid arrangement.

The grid arrangement may have meshes of about 500 micrometers to about 5000 micrometers square.

The dielectric anti-reflective coating may have a thickness of about 70 to about 100 nm.

The dielectric anti-reflective coating may be comprised of silicon nitride.

The dielectric anti-reflective coating may include an index of refraction of between about 2.0 and about 2.5.

The first conductive anti-reflective coating may include oxides of at least one of Indium, Tin, Titanium and Zinc.

The first conductive anti-reflective coating may include a fluoride-doped oxide of at least one of Indium and Tin.

The first conductive anti-reflective coating may have a thickness of between about 70 to about 100 nanometers.

The first conductive anti-reflective coating may have a refractive index of between about 1.7 and about 1.9.

The dielectric anti-reflective coating may have a refractive index of between about 2.0 and about 2.5 and the first conductive anti-reflective coating may have a refractive index of between about 1.7 and about 1.9.

In accordance with another aspect of the invention, there is provided a method of forming a photovoltaic semiconductor apparatus for use in forming a solar cell. The method involves forming a plurality of openings in a dielectric anti-reflective coating and a first passivation layer on a front side of a first doped volume of semiconductor material of a semiconductor wafer having first and second adjacent oppositely doped volumes of semiconductor material forming a heterojunction, to form passivated dielectric-coated areas on the front side and exposed portions of the front side of the first doped volume therebetween. The method also involves forming a first conductive anti-reflective coating on the passivated dielectric coated areas and the exposed areas of the front side surface.

Forming the plurality of openings may involve using a first material removal process to remove areas of the dielectric anti-reflective coating to expose portions of a surface of the first passivation layer and using a second process to remove portions of the first passivation layer to create the exposed areas of the front side surface.

The first process may involve at least one of laser ablation and selective plasma etching and the second process may involve wet chemical etching.

Wet chemical etching may involve wet chemical etching using fluoric acid.

The method may involve causing wet chemical etching to occur until the dielectric anti-reflective coating has a thickness between about 70 nanometers to about 100 nanometers.

Other aspects and features of the present invention will become apparent to those ordinarily skilled in the art upon review of the following description of specific embodiments of the invention in conjunction with the accompanying figures.

### BRIEF DESCRIPTION OF THE DRAWINGS

In drawings which illustrate embodiments of the invention,

FIG. 1 is a cross sectional view of a photovoltaic semiconductor apparatus according to a first embodiment of the invention.

FIG. 2 is a cross sectional view of the apparatus of FIG. 1 in a first stage of processing.

FIG. 3 is a cross sectional view of the apparatus of FIG. 1 in a second stage of processing.

FIG. 4 is a cross sectional view of the apparatus of FIG. 1 in a third stage of processing.

FIG. 5 is a cross sectional view of the apparatus of FIG. 1 in a fourth stage of processing.

FIG. 6 is a plan view of the apparatus of FIG. 1 showing openings in a passivation layer on a front surface of the apparatus of FIG. 1 are arranged in parallel lines.

FIG. 7 is a plan view of an apparatus according to a second embodiment in which openings in a passivation layer on a front surface of the apparatus of FIG. 1 are shown in parallel lines and cross parallel lines to form a grid arrangement.

FIG. 8 is a cross sectional view of the apparatus of FIG. 1 in a fifth stage of processing.

FIG. 9 is a cross sectional view of an apparatus according to a second embodiment of the invention in which a dielectric anti-reflective coating is applied to a passivation layer.

FIG. 10 is a cross sectional view of the apparatus of FIG. 9 showing portions of the dielectric antireflection coating removed.

FIG. 11 is a cross sectional view of the apparatus of FIG. 10 showing portions of the dielectric antireflection coating and the first passivation layer removed.

FIG. 12 is a cross sectional view of the apparatus of FIG. 11 showing portions of the dielectric antireflection layer and exposed portions of the outer surface of the first volume of the semiconductor wafer covered with a conductive anti-reflective coating.

FIG. 13 is a cross sectional view of the apparatus of FIG. 8 wherein the back side surface thereof is finished in a manner similar to the front side surface thereof.

FIG. 14 is a perspective view of the apparatus of FIG. 13 shown in a stage of manufacturing in which first and second electrodes are connected to front and back side surfaces.

FIG. 15 is a cross sectional view of an apparatus of FIG. 8 wherein the back side is finished with a third doped volume and a conductive coating.

FIG. 15A is a fragmented magnified cross sectional view of a portion of the apparatus shown in FIG. 15.

FIG. 16 is a cross sectional view of the apparatus of FIG. 8 wherein the back side is finished with a layer of aluminium with laser-fired contacts.

### DETAILED DESCRIPTION

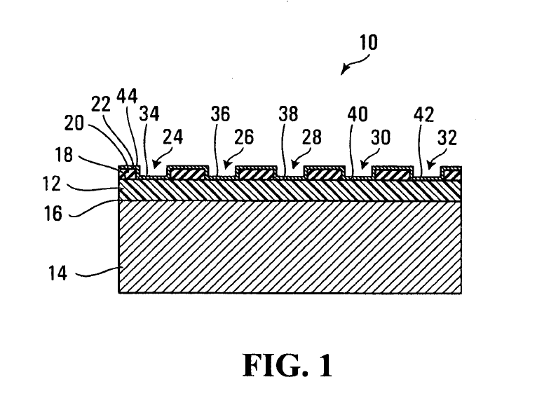

Referring to FIG. 1, a photovoltaic semiconductor apparatus for use in forming a solar cell is shown generally at 10. The apparatus 10 includes first and second adjacent oppositely doped volumes 12 and 14 of semiconductor material forming a semiconductor heterojunction 16. The first doped volume acts as an emitter. These volumes 12, 14 may be provided in a semiconductor wafer according to conventional thermal diffusion or ion implantation techniques, for example. The first doped volume 12 has a front side surface 18. A first passivation layer 20 is disposed on the front side surface 18. The first passivation layer 20 has a first outer surface 22 and a plurality of openings, only five of which are shown at 24, 26, 28, 30, and 32, that define corresponding unpassivated areas 34, 36, 38, 40, and 42 of the front side surface 18 that are unpassivated by the first passivation layer 20. While only five openings are shown for explanatory purposes, in practice there may be a much larger number of openings. A first conductive anti-reflective coating 44 is disposed on the first outer surface 22 of the passivation layer and on the unpassivated areas 34, 36, 38, 40, and 42 of the front side surface 18.

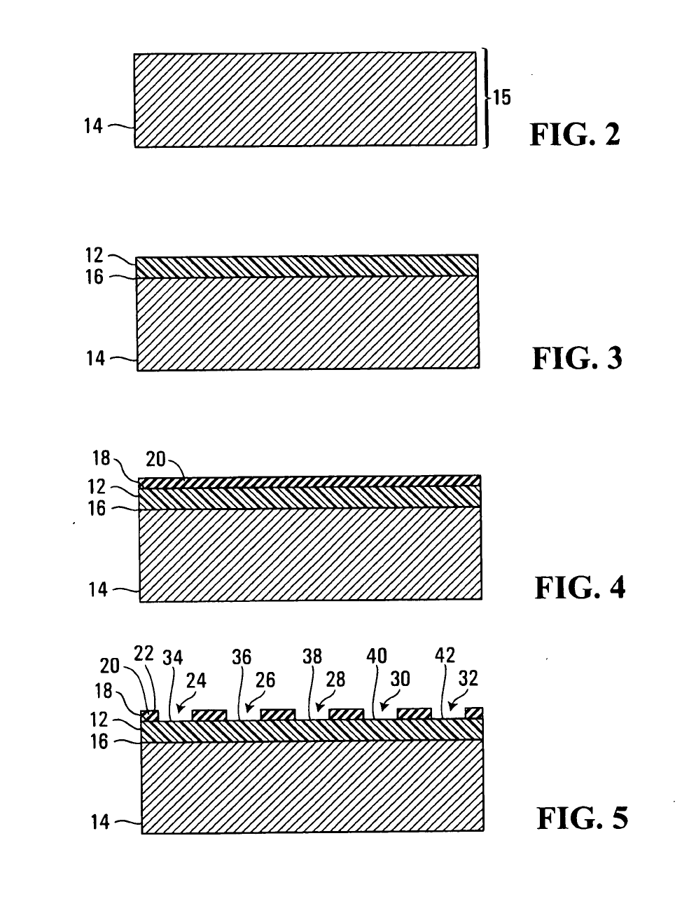

Referring to FIGS. 2 and 3, to make the apparatus shown in FIG. 1, a crystalline silicon wafer 15 is doped with appropriate doping elements of opposite polarity to create the first and second volumes 12 and 14 and the heterojunction 16 therebetween. Typically a pre-doped p- or n-type crystalline silicon wafer 15 is first etched using wet plasma etching technology to remove saw damage from the silicon wafer. The front surface of the wafer is then textured using wet technology to reduce the amount of solar radiation reflected from the front surface when in use.

If the crystalline silicon wafer 15 is pre-doped to become p-type semi-conductor material, then the first doped volume 12 is usually formed by doping a front side of the wafer with phosphorous and if the silicon wafer is initially n-type, then its front side is usually doped with boron. Doping may be achieved by ion implantation which facilitates penetration of boron or phosphorous ions into the pre-doped semiconductor material providing for shallow emitter formation with sharp cut-off p/n junction barrier. These properties facilitate better p/n junction performance in charge separation and sensitivity in the blue spectral region. Subsequent annealing activates doped elements within the first doped volume on one side of the heterojunction 16 which defines the first and second doped volumes 12 and 14 within the silicon wafer 15. Alternatively, the first and second doped volumes 12 and 14 may be produced by conventional thermal diffusion of gas containing phosphorous or boron dopant atoms and subsequent annealing as described above. Desirably, the first doped volume 12 has a sheet resistivity of about 80 to about 150 ohms per square. Alternatively, the initially doped semiconductor material may be further doped by applying solid phosphorous or boron doping sources on the semiconductor material followed by subsequent firing diffusion and annealing. However, ion implantation techniques consume substantially less energy than conventional thermal diffusion processes and are therefore favoured over thermal diffusion techniques.

Referring to FIG. 4, to produce the first passivation layer of material on the front side surface 18, silicon dioxide (SiO₂), silicon nitride (SiN₄), or silicon carbide (SiC) is deposited using low pressure chemical vapour deposition techniques, plasma enhanced chemical vapour deposition techniques or other appropriate methods. Desirably, the first passivation layer 20 has a thickness of about 10 nanometers to about 500 nanometers and more desirably has a thickness of about 10 nanometers to about 50 nanometers.

Referring to FIG. 5, openings 24, 26, 29, 30 and 32 are formed by laser ablation or selective plasma etching of the first passivation layer 20, for example, to define the unpassivated areas 34, 36, 38, 40, and 42 respectively.

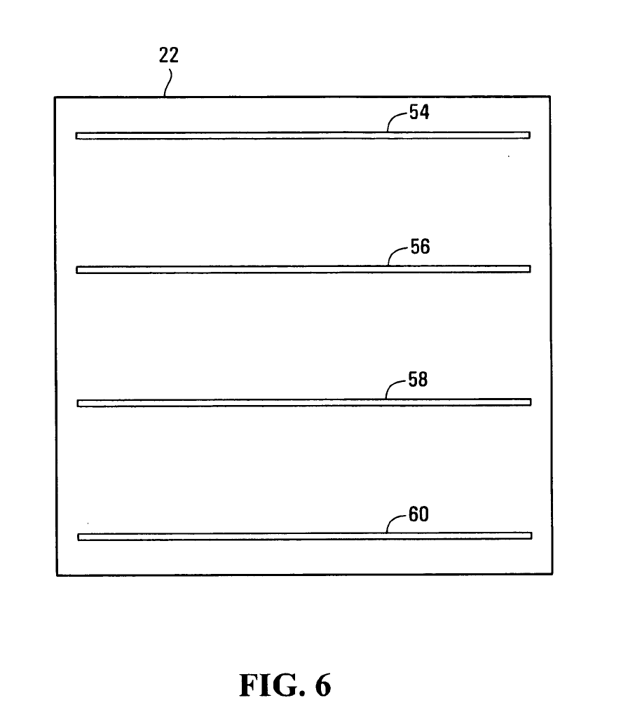

Referring to FIG. 6, the openings in the first passivation layer may be arranged in spaced apart parallel lines 54, 56, 58, and 60 across the first outer surface 22. The width of the lines may be between about 50 micrometers to about 200 micrometers and the distance between parallel lines may be about 500 micrometers to about 5000 micrometers, for example.

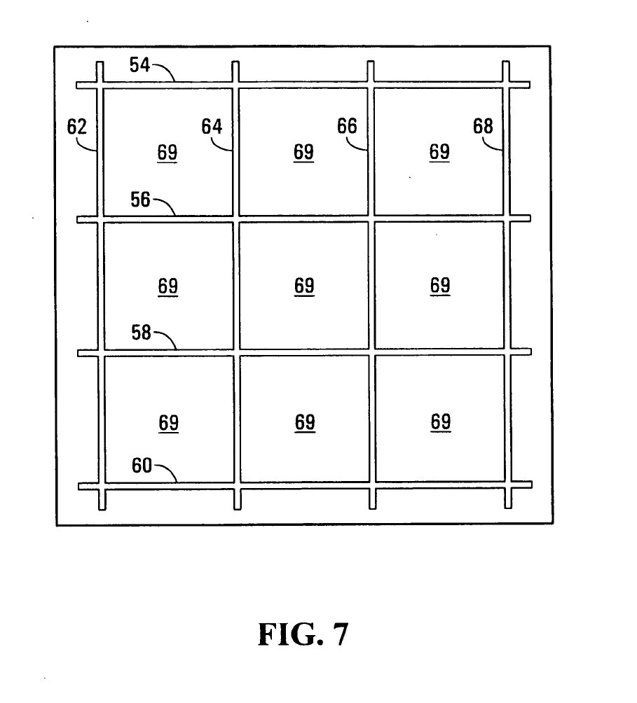

Referring to FIG. 7, in an alternate embodiment the parallel lines 54, 56, 58, and 60 are connected by cross parallel lines 62, 64, 66, and 68 to form a grid arrangement. The grid arrangement may have meshes 69 about 500 micrometers to about 5000 micrometers square.

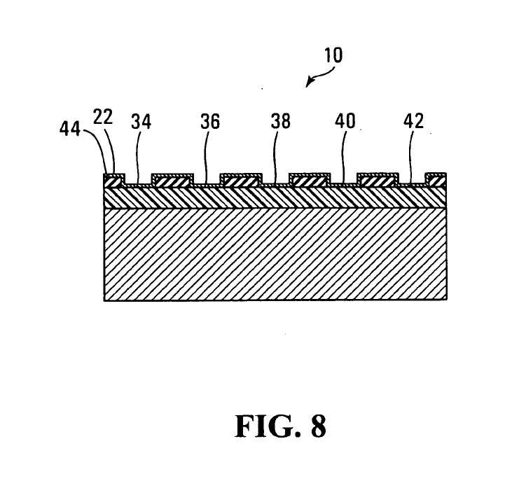

Referring to FIG. 8, after having formed a plurality of openings in the first passivation layer 20, the first conductive anti-reflective coating 44 comprised of at least one of InOx, SnOx, InSnOx, TiOx or ZnOx is applied by chemical vapour deposition, sputtering or other conventional methods. Desirably, the first conductive anti-reflective coating 44 is formed across the surface defined by the first outer surface 22 of the passivation layer and the unpassivated areas 34, 36, 38, 40, and 42 to provide a continuous coating all across the top of the wafer. Continuous means that there are no breaks in the first conductive anti-reflective coating 44 across the entire surface, even though the first conductive anti-reflective coating has a somewhat serpentine shape in cross section. Desirably, the first conductive anti-reflective coating 44 has a thickness of between about 70 nanometers to about 280 nanometers, depending upon the desirable emitter sheet conductivity and spectral sensitivity of semiconductor apparatus. Also desirably, the first anti-reflective coating has a sheet resistivity of between about 1 ohm per square to about 30 ohms per square.

After completing the third step shown in FIG. 8, the front side of apparatus 10 is thus completed and ready to receive an electrode as will be described below.

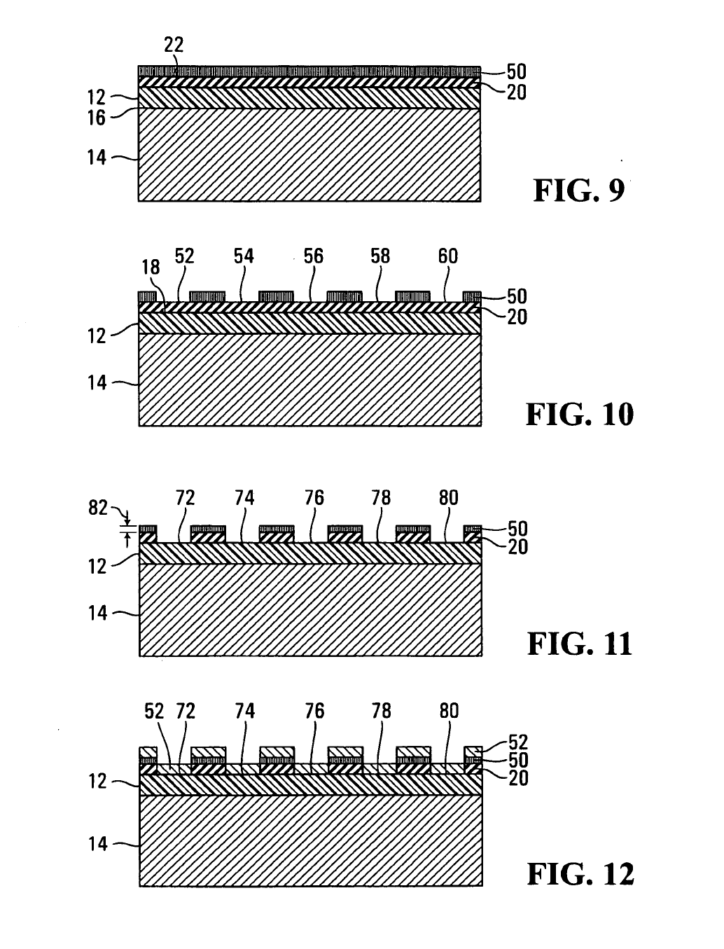

In an alternative embodiment, referring to FIGS. 4 and 9, a dielectric anti-reflective layer or coating 50 may be deposited on the outer surface 22 of the first passivation layer 20, before forming openings as described above. Desirably, the dielectric anti-reflective coating 50 will have an initial thickness of between about 100 to about 150 nanometers. The refractive index of the dielectric anti-reflective coating 50 should be preferably in the range of about 2.0 to about 2.5 and the dielectric anti-reflective coating 50 must be able to tolerate exposure to temperatures of about 700 degrees Celcius for at least 10 minutes, without degradation to its integrity and refractive index. A suitable dielectric anti-reflective coating 50 with these properties may be produced using silicon nitride spattering, silicon nitride reactive spattering, plasma enhanced chemical vapour deposition or other appropriate methods. The use of a silicon nitride dielectric anti-reflective coating 50 is desirable because silicon nitride films can be removed by laser ablation or etched with fluoric acid. When etched, the speed of etching preferably should be about ten times slower than that of etching silicon dioxide films under the same conditions.

Referring to FIG. 10, openings 52, 54, 56, 58 and 60 are formed in the dielectric anti-reflective coating 50 by a first material removal process such as laser ablation or selective plasma etching or other appropriate methods that remove certain areas of the dielectric anti-reflective coating 50. It is desirable to terminate the laser ablation or selective plasma etching process as soon as the dielectric anti-reflective coating 50 is almost removed such that residual portions of the dielectric anti-reflective coating remain and the surface of the first passivation layer 20 is almost exposed, as shown in areas 72, 74, 76, 78, and 80.

The apparatus of FIG. 10 is then subjected to a second material removal process such as wet chemical etching with fluoric acid until the residual portions of the dielectric anti-reflective coating and the first passivation layer 20 are etched away, leaving corresponding areas 72, 74, 76, 78 and 80 of the front side surface 18 of the first doped volume 12 exposed and unpassivated as shown in FIG. 11. It will be appreciated that during the process of wet chemical etching with fluoric acid, the dielectric anti-reflective coating 50 becomes thinner due to partial etching. After this partial etching the final thickness 82 of the dielectric anti-reflective coating 50 should be between about 70 to about 100 nanometers.

Next, a conductive anti-reflective coating 52 comprising conductive oxides of Indium or Tin, or Zinc, or Titanium or a combination of these materials is applied to the apparatus such that the conductive anti-reflective coating is formed on top of the dielectric anti-reflective coating 50 and on the exposed areas 72, 74, 76, 78 and 80 of the front side surface 18 of the first doped volume 12, as shown in FIG. 12. Fluoride-doped oxides of Indium, Tin, Titanium, or Zinc or a mixture of Indium and Tin are preferred for use as the conductive anti-reflective coating 52. The conductive anti-reflective coating 52 should have a thickness of about 70 to about 100 nanometers and should have a refractive index of the about 1.7 to about 1.9.

The dielectric anti-reflective coating 50 shields the first passivation layer 20 from fluoric acid wet etching and the combination of the dielectric anti-reflective coating and the conductive anti-reflective coating minimizes reflection of incident solar radiation from the front side surface 18 of the photovoltaic apparatus.

It is well known that the light reflection from any material is determined by the difference of refraction indexes between two neighbouring materials according to the formula: (n₁−n₂)²/(n₁+n₂)², subject to the condition that the thickness of each material layer is higher that a quarter of the wavelength or >80 nanometers. If the refractive index of silicon is about 4.0 and the refractive index of the conductive anti-reflective coating is about 1.7, then the total reflection at areas where the conductive anti-reflective coating is directly on the exposed areas of the front side surface 18 of the first doped volume is about 16%. Where the front side surface 18 is coated with the dielectric anti-reflective coating 50 and the dielectric anti-reflective coating has a refractive index of about 2.2 the total reflection becomes substantially lower of 8%. In the areas where the conductive anti-reflective coating 52 (refractive index 1.7) is on the dielectric anti-reflective coating 50 (refractive index 2.2) the overall reflection is decreased to 1.6%. Consequently, more light is admitted into the front side surface which results in a corresponding increase in the conversion efficiency of the photovoltaic apparatus.

It is also important to note that since the first doped volume 12 is essentially a shallow emitter, there is a risk that there may be a certain number of holes that can give rise to negative shunting. In the embodiment shown the dielectric anti-reflective coating 50 insulates the conductive anti-reflective coating 52 from direct contact with the first doped volume 12 (emitter) in the areas adjacent the openings 72, 74, 76, 78 and 80 which reduces the potential for shunting through the emitter.

The configuration shown in FIG. 12 is suitable for use whether the first volume 12 is p-type or n-type. Where the first volume 12 is p-type, the first conductive anti-reflective coating 52 may be formed from an oxide of Tin, for example, since such material interacts favourably with p-type material.

Where the first volume 12 is n-type, the first conductive anti-reflective coating 52 may be an oxide of Indium, for example, since such material interacts favourably with n-type material.

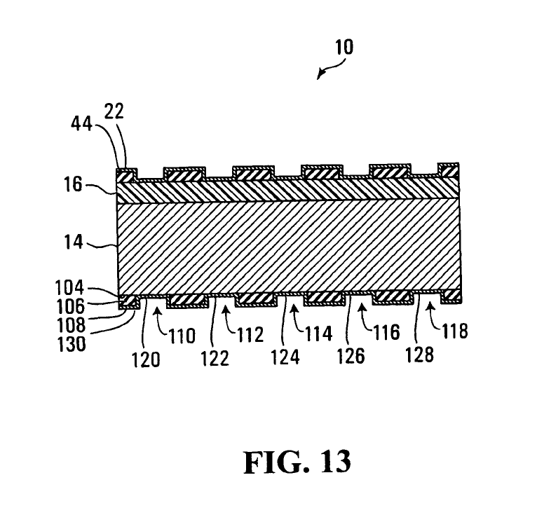

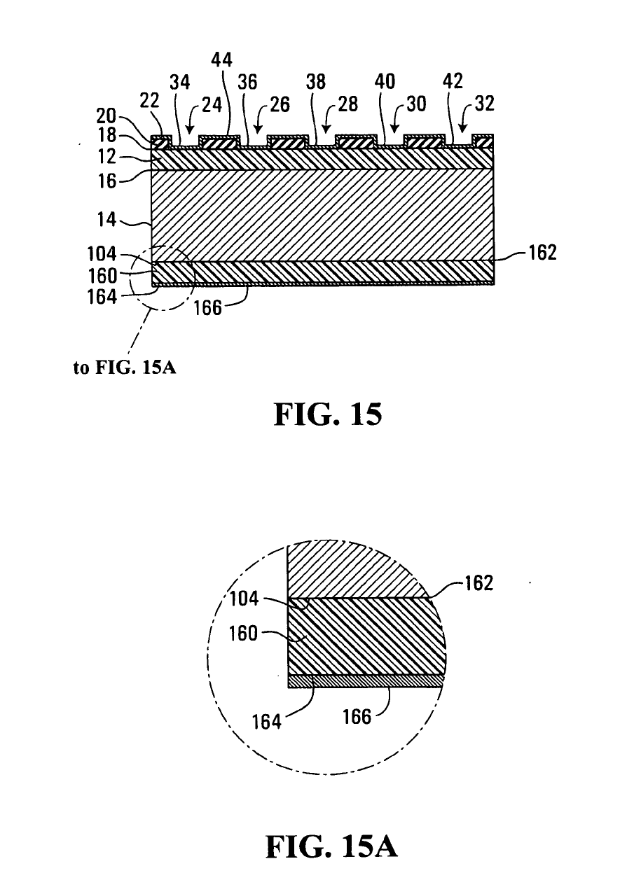

Referring to FIG. 13, the second doped volume 14 has a back side surface 104 that may be finished in a plurality of different ways. For example, the back side surface 104 may be finished similarly to the front side surface 18 with a second passivation layer having openings and a second conductive anti-reflective coating as shown in FIG. 13. Alternatively, the back side surface 104 may be finished by forming a third doped volume adjacent the second doped volume and forming a conductive anti-reflection coating on the outer surface of the third volume as shown in FIG. 15. Or, the back side surface 104 may be covered with a second passivation layer and a layer of aluminium, and a plurality of laser-fired contacts may be formed therein. Each of these alternative methods for finishing the back side surface is described below.

Referring to FIG. 13, in one embodiment the back side surface 104 of the second doped volume 14 may be configured in a manner similar to the front side shown in FIG. 1. In particular, the apparatus shown in FIG. 8 is subjected to further processing in which a second passivation layer 106 is provided on the back side surface 104. The second passivation layer 106 may be comprised of SiO₂, SiN₄, or SiC, for example and may be formed to have a thickness of about 10 nm to about 500 nm and desirably about 10 nm to about 50 nm. The second passivation layer 106 has a second outer surface 108 and a second plurality of openings therethrough, the openings being shown generally at 110, 112, 114, 116, and 118. The openings 110, 112, 114, 116, and 118 define respective unpassivated areas 120, 122, 124, 126, and 128 of the back side surface 104 that are unpassivated by the second passivation layer 106. The openings in the second passivation layer may be arranged in spaced apart parallel lines as shown in FIG. 6, for example. The width of the lines may be between about 50 micrometers to about 200 micrometers and the distance between parallel lines may be about 500 micrometers to about 5000 micrometers, for example.

After having formed a plurality of openings in the second passivation layer 106, the second conductive anti-reflective coating 130 comprised of at least one of InOx, SnOx, InSnOx, TiOx or ZnOx is applied by chemical vapour deposition, sputter or other methods. Desirably, the second conductive anti-reflective coating 130 is comprised of an oxide of Indium, where the second volume 14 of semiconductor material is comprised of n-type material and the second conductive anti-reflective coating 130 is comprised of an oxide of Tin where the second volume 14 of semiconductor material is comprised of p-type material. Also desirably, the second conductive anti-reflective coating 130 is formed across the surface defined by the second outer surface 108 of the passivation layer and the unpassivated areas 120, 122, 124, 126, and 128 to provide a continuous coating all across the back side of the wafer. Continuous means that there are no breaks in the second conductive anti-reflective coating 130 across the entire surface, even though the second conductive anti-reflective coating has a somewhat serpentine shape in cross section. Desirably, the second conductive anti-reflective coating 130 has a thickness that is about the same as or greater than the thickness of the first conductive anti-reflective coating 44. In this regard, the second conductive anti-reflective coating 130 may have a thickness of about 70 nanometers to about 500 nanometers. Desirably, the second anti-reflective coating has a sheet resistivity of about 1 ohm per square to about 30 ohms per square.

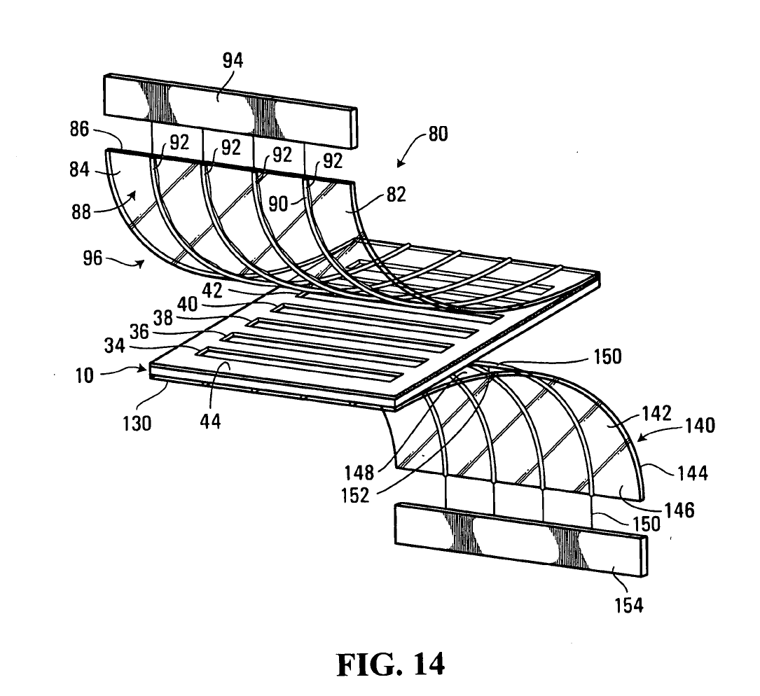

With both the front side and back side of the apparatus prepared as described above, the apparatus is ready to receive first and second electrodes respectively. Referring to FIG. 14, first and second electrodes are shown generally at 80 and 140 being applied to the front and back sides of the apparatus respectively. The first electrode 80 is comprised of a first optically transparent electrically insulating film 82 having first and second opposite sides 84 and 86 respectively. The first optically transparent electrically insulating film 82 may include a polyester film, for example and may have a thickness of about 6 microns to about 100 microns. The first side 84 has a first adhesive coating 88 for adhering the first insulating optically transparent film 82 to the first conductive anti-reflective coating 44 on the semiconductor apparatus 10. Desirably, the adhesive coating has thermoplastic properties and becomes fluid when subjected to temperatures of about 60 degrees Celsius to about 140 degrees Celsius, or perhaps more desirably, when subjected to a temperature in the range of between about 80 degrees Celsius and about 130 degrees Celsius. The adhesive may have a thickness of about 15 microns and about 130 microns, for example.

A plurality of conductors, one of which is shown at 90, are embedded in the first adhesive coating 88 such that portions 92 protrude from the first adhesive coating 88. The portions 92 of the conductors 90 are soldered to the first conductive anti-reflective coating 44 by heating and pressing an alloy which may be provided as a coating pre-formed on the exposed portions of the conductors 90. The alloy may include a composition including at least two of Ag, Bi, Cd, Ga, In, Pb, Sb, Sn, and Zn. For example the alloy may include a composition including In, Sn, Ag in a proportion of about 47% In, about 51% Sn, and about 2% Ag. Alternatively, the alloy may include In and Sn in a proportion of about 48% In and about 52% Sn. The alloy may have a thickness of about 1 micron to about 5 microns and may have a melting temperature about 30° Celsius to about 200° Celsius. More particularly, the alloy may have a melting temperature of between about 60° Celsius and about 150° Celsius.

Soldering the portions 92 to the first conductive anti-reflective coating 44 forms ohmic connections between the portions 92 of the conductors, and the first conductive anti-reflective coating 44, such that electrons can pass between the unpassivated areas 34, 36, 38, 40, and 42 and the first conductive anti-reflective coating 44 and the portions 92 of the conductors embedded in the adhesive on the first electrode 80 to permit an electric current generated by the photovoltaic semiconductor apparatus 10 to be conducted by the conductors 90. The conductors 90 are connected to a bus bar 94 which acts as a first terminal that collects current from the conductors and enables the photovoltaic cell to be connected to an electrical circuit.

Further details of general and alternate constructions of the first electrode 80 may be obtained from applicant's International Patent Application published under International Publication Number WO 2004/021455A1, which is incorporated herein by reference.

The second electrode is shown generally at 140 and is applied to the second conductive anti-reflective coating 130. The second electrode 140 is similar to the first electrode 80, in that it includes a second electrically insulating film 142 having first and second opposite sides 144 and 146. The second insulating film need not be optically transparent. The first side 144 of the second film 142 has a second adhesive coating 148 for adhering the second film to the second conductive anti-reflective coating 130. A second plurality of conductors 150 are embedded in the second adhesive coating 148 such that portions 152 protrude from the second adhesive coating and are soldered to the second conductive anti-reflective coating 130 by heating and pressing an alloy coating thereon, as described above, to form ohmic connections between the portions of the conductors 150 and the second conductive anti-reflective coating 130. Electrons can therefore pass between the conductors 150, and the second conductive anti-reflective coating and the unpassivated areas (not shown in FIG. 14) on the back side surface 104 to permit electric current generated by the photovoltaic semiconductor apparatus 10 to be supplied to an electrical circuit. A second bus bar 154 is connected to the conductors to provide a second terminal for connecting the photovoltaic cell to an electrical circuit. Thus, in this embodiment the bus bars 94 and 154 shown in FIG. 14 act as positive and negative terminals, respectively, of the solar cell.

Referring to FIGS. 15 and 15A, alternatively, the back side surface 104 of the apparatus shown at 10 may be finished with a third doped volume 160 adjacent the second doped volume 14 on a side of the second doped volume opposite the semiconductor heterojunction 16. The third doped volume 160 has the same doping polarity as the second doped volume 14, thereby forming an isotype junction 162. The third doped volume 160 has a doping concentration greater than a doping concentration of the second doped volume 14 and has a back side surface 164. Doping to form the third doped volume 160 may be achieved by ion implantation or diffusion from a gaseous environment that contains appropriate doping elements, for example.

A second conductive anti-reflective coating 166 is provided on the back side surface 164 of the third doped volume 160. Desirably, the second conductive anti-reflective coating 166 is continuous and has a thickness that is about the same as or greater than the thickness of the first conductive anti-reflective coating 44. In this regard, the second conductive anti-reflective coating 166 may have a thickness of between about 70 nanometers to about 500 nanometers. The second conductive anti-reflective coating 166 may be comprised of at least one of InOx, SnOx, InSnOx, TiOx and ZnOx. Desirably, the second conductive anti-reflective coating has a sheet resistivity of between about 1 ohms per square to about 30 ohms per square.

The first and second electrodes 80 and 140 are secured to the front side of the apparatus and to the second conductive anti-reflective coating 166 of the third doped volume 160, respectively, in the same manner as described above in connection with FIG. 10 wherein the portions of the conductors 90 of the first electrode 80 are soldered to the first conductive anti-reflective coating 44 by heating and pressing an alloy coating on the portions 92 to form ohmic connections between the first conductive anti-reflective coating 44 and the portions 92 of the first plurality of conductors 90 such that electrons can pass between the unpassivated areas 34, 36, 38, 40, and 42 of the front side surface 18 and the first plurality of conductors 90 to permit an electric current generated by the photovoltaic semiconductor apparatus to be conducted by the first plurality of conductors 90. In addition, the portions 152 of the second plurality of conductors 150 of the second electrode 140 are soldered to the second conductive anti-reflective coating 166 by heating and pressing an alloy coating on those portions 152 to form ohmic connections between the portions 152 of the second plurality of conductors 150 and the second conductive anti-reflective coating 166 such that electrons can pass between the second plurality of conductors 150 and the back side surface 164 of the third doped volume 160 to permit the electric current generated by the photovoltaic semiconductor apparatus to be conducted by the second plurality of conductors 150.

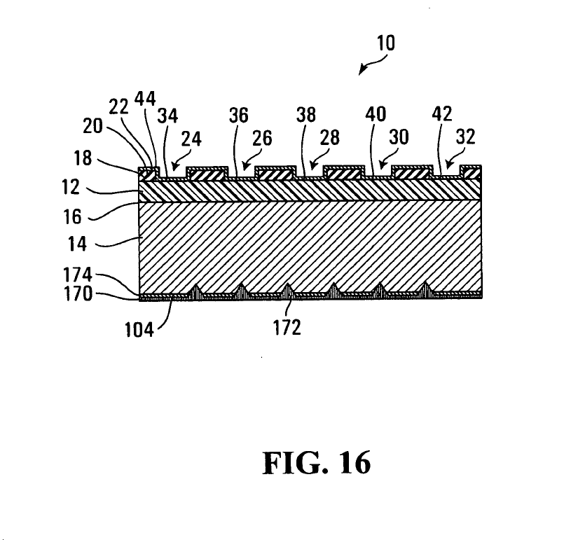

Referring to FIG. 16, in another alternate embodiment, the back side surface 104 of the apparatus 10 is finished with layer of aluminum 170 that is deposited onto the second passivation layer 174 and laser-fired contacts that are formed through the second passivation layer between the layer of aluminum 170 and second doped volume 14. First, a second continuous passivation layer 174 is formed on the back side surface 104 of the second doped volume 14. The second passivation layer 174 may be formed by low pressure chemical vapour deposition or plasma enhanced chemical vapour deposition of SiO₂, SiN₄, or SiC, for example, onto the back side surface 104 of the second doped volume 14. The second passivation layer 174 may be formed to have a thickness of about 10 nm to about 500 nm and more desirably about 10 nm to about 50 nm.

The layer of aluminum 170 is then formed on the surface of the second passivation layer 174, using vacuum evaporation or sputtering techniques. The layer of aluminum 170 may be formed to have a thickness of about 1 micrometer to about 20 micrometers and more desirably to have a thickness of about 2 micrometers to about 10 micrometers.

The laser-fired contacts 172 are laser-fired into the layer of aluminum using conventional techniques that cause portions of the layer of aluminum 170 to burn through the second passivation layer 174 and form an alloy with the second doped volume 14, thereby creating a back surface field and current collecting contacts.

To form a solar cell using the semiconductor apparatus shown in FIG. 16, first and second electrodes 80 and 140 such as shown in FIG. 14 are connected to the first conductive anti-reflective coating 44 and the layer of aluminum to permit electric current to be supplied by the semiconductor apparatus to an external circuit. For the first electrode 80, the portions 92 of the conductors that are exposed are soldered to the first conductive anti-reflective coating 44 by heating and pressing the alloy coating on those exposed portions to form ohmic connections between the first conductive anti-reflective coating 44 and the portions 92 of the first plurality of conductors 90 such that electrons can pass between the unpassivated areas 34, 36, 38, 40, and 42 of the front side and the first plurality of conductors 90 to permit an electric current generated by the photovoltaic semiconductor apparatus to be conducted by the first plurality of conductors 90. For the second electrode 140, the exposed portions 152 of the second plurality of conductors 150 are soldered to the layer of aluminum 170 by heating and pressing an alloy coating on those portions 152 to form ohmic connections between the portions 152 of the second plurality of conductors 150 and the second doped volume 14 through the laser fired contacts 172 to permit the electric current generated by the photovoltaic semiconductor apparatus to be conducted by the second plurality of conductors 150.

The present invention provides a photovoltaic cell that has a shallow emitter that is generally uniform in thickness and thus there is no need to selectively form emitter areas of different thicknesses. In addition, since the emitter is shallow, the apparatus is more responsive to blue light than devices with emitters of non-uniform thickness, making the overall device more efficient in converting light energy into electrical energy.

In addition, the methods and apparatus described herein do not require screen printing technology, which eliminates several time and energy consuming manufacturing steps and reduces susceptibility to bowing that can be caused by use of conductive pastes on the front and back surfaces of the cell.

In addition, the lack of any need for screen printing technology allows solar cells to be manufactured more quickly and at less cost.

In addition the avoidance of the use of screen printing technology allows the formation of substantially thinner emitters without risk of emitter shunting.

In addition the combination provided by the passivation layer with openings and the conductive anti-reflective coating facilitates efficient current collection while simultaneously providing semiconductor surface passivation

In addition, the methods and apparatus described herein allow the use of ion implantation as an alternative to thermal diffusion for hetero- and isotype junction formation thus decreasing manufacturing energy consumption and manufacturing costs.

Finally, the use of the conductive coatings on at least the front surface of the solar cell and the use of first and second electrodes soldered to the first and second conductive anti-reflective coating and the back side surface respectively obviates the need to precisely align the conductors on the electrodes with pre-printed contacts. Precise alignment of the electrodes so that the conductors on the electrodes align with pre-formed contacts on the front and back surfaces is not necessary, enabling a relaxation of manufacturing tolerances in solar cell manufacturing, which further decreases production costs.

While specific embodiments of the invention have been described and illustrated, such embodiments should be considered illustrative of the invention only and not as limiting the invention as construed in accordance with the accompanying claims.

What is claimed is:

1. A photovoltaic semiconductor apparatus for use in forming a solar cell comprising:
first and second adjacent oppositely doped volumes of semiconductor material forming a semiconductor heterojunction, said first doped volume acting as an emitter having a front side for receiving light;
a first passivation layer of material on said front side, said first passivation layer having a first outer surface and a plurality of openings therethrough defining corresponding unpassivated areas of said front side that are unpassivated by said first passivation layer; and
a first conductive anti-reflective coating on said first outer surface of said passivation layer and on said corresponding unpassivated areas of said front side.

2. The apparatus of claim 1 wherein said semiconductor heterojunction is at least one of an ion-implanted heterojunction and a thermally diffused heterojunction.

3. The apparatus of claim 1 wherein said first doped volume has a sheet resistivity of about 60 ohms per square to about 150 ohms per square.

4. The apparatus of claim 1 wherein said first doped volume has a sheet resistivity of about 80 ohms per square to about 150 ohms per square.

5. The apparatus of claim 1 wherein said first passivation layer is comprised of at least one of SiO₂, SiN₄ and SiC.

6. The apparatus of claim 1 wherein said first passivation layer has a thickness of about 10 nm to about 500 nm.

7. The apparatus of claim 6 wherein said first passivation layer has a thickness of about 10 nm to about 50 nm.

8. The apparatus of claim 1 wherein said openings have a width of about 50 micrometers to about 200 micrometers

9. The apparatus of claim 1 wherein said openings in said first passivation layer are arranged in parallel lines across said first outer surface.

10. The apparatus of claim 9 wherein said parallel lines are spaced apart by about 500 micrometers to about 5000 micrometers.

11. The apparatus of claim 8 wherein said parallel lines are connected by cross parallel lines to form a grid arrangement.

12. The apparatus of claim 11 wherein said grid arrangement has meshes of about 500 micrometers to about 5000 micrometers square.

13. The apparatus of claim 1 wherein said first conductive anti-reflective coating is continuous.

14. The apparatus of claim 1 wherein said first conductive anti-reflective coating has a thickness of about 70 to about 280 nm.

15. The apparatus of claim 1 wherein said first conductive anti-reflective coating is comprised of at least one of: InOx, SnOx, InSnOx, TiOx and ZnOx.

16. The apparatus of claim 1 wherein said first conductive anti-reflective coating has a sheet resistivity of between about 1 Ohm/sq. to about 30 Ohm/sq.

17. The apparatus of claim 1 further comprising:
a second passivation layer on said back side surface, said second passivation layer having a second outer surface having a second plurality of openings therethrough defining corresponding unpassivated areas of said second outer surface that are unpassivated by said second passivation layer; and
a second conductive anti-reflective coating on said second outer surface of said second passivation layer and on said corresponding unpassivated areas of said second outer surface.

18. The apparatus of claim 17 wherein said second passivation layer is comprised of at least one of SiO₂, SiN₄ and SiC.

19. The apparatus of claim 17 wherein said second passivation layer has a thickness of about 10 nm to about 500 nm.

20. The apparatus of claim 17 wherein said second passivation layer has a thickness of about 10 nm to about 50 nm.

21. The apparatus of claim 17 wherein said openings in said second passivation layer have a width of about 50 micrometers to about 200 micrometers.

22. The apparatus of claim 17 wherein said openings in said second passivation layer are arranged in parallel lines across said second outer surface.

23. The apparatus of claim 22 wherein said between parallel lines are spaced apart by about 500 micrometers to about 5000 micrometers.

24. The apparatus of claim 23 wherein said parallel lines are connected by cross parallel lines to form a grid arrangement.

25. The apparatus of claim 24 wherein said grid arrangement has meshes of approximately about 500 micrometers to about 5000 micrometers square.

26. The apparatus of claim 17 wherein said second conductive anti-reflective coating is continuous.

27. The apparatus of claim 17 wherein said second conductive anti-reflective coating has a thickness that is about at least as thick as said first conductive anti-reflective coating.

28. The apparatus of claim 17 wherein said second conductive anti-reflective coating has a thickness of between about 70 to about 500 nm.

29. The apparatus of claim 17 wherein said second conductive anti-reflective coating is comprised of at least one of: InOx, SnOx, InSnOx, TiOx and ZnOx.

30. The apparatus of claim 17 wherein said second conductive anti-reflective coating has a sheet resistivity of about 1 Ohm/sq. to about 30 Ohm/sq.

31. A solar cell apparatus comprising the apparatus of claim 17 and further comprising a first electrode comprising:
a first optically transparent electrically insulating film having first and second opposite sides;
said first side having a first adhesive for adhering said first film to said first conductive anti-reflective coating,
a first plurality of conductors embedded in said first adhesive such that portions of said first plurality of conductors protrude from said first adhesive;
said portions being soldered to said first conductive anti-reflective coating by an alloy coating on said portions to form ohmic connections between said first conductive anti-reflective coating and said portions of said first plurality of conductors such that electrons can pass between said unpassivated areas of said front side and said first plurality of conductors to permit an electric current generated by said photovoltaic semiconductor apparatus to be conducted by said first plurality of conductors.

32. A solar cell apparatus comprising the apparatus of claim 31 and further comprising a second electrode comprising:
a second electrically insulating film having first and second opposite sides;
said first side of said second film having a second adhesive for adhering said second film to said second conductive anti-reflective coating;
a second plurality of conductors embedded in said second adhesive such that portions of said second plurality of conductors protrude from said second adhesive;
said portions of said second plurality of conductors being soldered to said second conductive anti-reflective coating by an alloy coating on said portions to form ohmic connections between said portions of said second plurality of conductors and said second conductive anti-reflective coating such that electrons can pass between said unpassivated areas of said second outer surface and said second plurality of conductors to permit the electric current generated by said photovoltaic semiconductor apparatus to be conducted by said second plurality of conductors.

33. The apparatus of claim 1 further comprising a third doped volume adjacent said second doped volume on a side of said second doped volume opposite said semiconductor heterojunction, said third doped volume having the same doping polarity as said second doped volume thereby forming an isotype junction with said second doped volume and wherein said third doped volume has a doping concentration greater than a doping concentration of said second doped volume and wherein said third doped volume has a back side surface.

34. The apparatus of claim 33 further comprising a second conductive anti-reflective coating on said back side surface of said third doped volume.

35. The apparatus of claim 34 wherein said second conductive anti-reflective coating has a thickness that is about the same as, or greater than, a thickness of said first conductive anti-reflective coating.

36. The apparatus of claim 34 wherein said second conductive anti-reflective coating has a thickness of about 70 to about 500 nm.

37. The apparatus of claim 34 wherein said second conductive anti-reflective coating is comprised of at least one of: InOx, SnOx, InSnOx, TiOx and ZnOx.

38. The apparatus of claim 34 wherein said second conductive anti-reflective coating has a sheet resistivity of about 1 Ohm/sq. to about 30 Ohm/sq.

39. A solar cell apparatus comprising the apparatus of claim 34 and further comprising a first electrode comprising:
a first optically transparent electrically insulating film having first and second opposite sides;
said first side having a first adhesive for adhering said first film to said first conductive anti-reflective coating,
a first plurality of conductors embedded in said first adhesive such that portions of said first plurality of conductors protrude from said first adhesive;
said portions being soldered to said first conductive anti-reflective coating by an alloy coating on said portions to form ohmic connections between said first conductive anti-reflective coating and said portions of said first plurality of conductors such that electrons can pass between said unpassivated areas of said front side and said first plurality of conductors to permit an electric current generated by said photovoltaic semiconductor apparatus to be conducted by said first plurality of conductors.

40. A solar cell apparatus comprising the apparatus of claim 39 and further comprising a second electrode comprising:
a second electrically insulating film having first and second opposite sides;
said first side of said second film having a second adhesive for adhering said second film to said second conductive anti-reflective coating;
a second plurality of conductors embedded in said second adhesive such that portions of said second plurality of conductors protrude from said second adhesive;
said portions of said second plurality of conductors being soldered to said second conductive anti-reflective coating by an alloy coating on said portions to form ohmic connections between said portions of said second plurality of conductors and said second conductive anti-reflective coating such that electrons can pass between said back side surface of said third volume and said second plurality of conductors to permit the electric current generated by said photovoltaic semiconductor apparatus to be conducted by said second plurality of conductors.

41. The apparatus of claim 1 wherein said second doped volume has a back side surface and further comprising:
a second passivation layer on said back side surface; and
a layer of aluminum on said second passivation layer, said layer of aluminum having a plurality of laser-fired current collecting contacts extending from said aluminum layer through second passivation layer to said second doped volume.

42. A solar cell apparatus comprising the apparatus of claim 41 and further comprising a first electrode comprising:
a first optically transparent electrically insulating film having first and second opposite sides;
said first side having a first adhesive for adhering said first film to said first conductive anti-reflective coating,
a first plurality of conductors embedded in said first adhesive such that portions of said first plurality of conductors protrude from said first adhesive;
said portions being soldered to said first conductive anti-reflective coating by an alloy coating on said portions to form ohmic connections between said conductive anti-reflective coating and said portions of said first plurality of conductors such that electrons can pass between said unpassivated areas of said front side and said first plurality of conductors to permit an electric current generated by said photovoltaic semiconductor apparatus to be conducted by said first plurality of conductors.

43. A solar cell apparatus comprising the apparatus of claim 42 and further comprising a second electrode comprising:
a second electrically insulating film having first and second opposite sides;
said first side of said second film having a second adhesive for adhering said second film to said layer of aluminum;
a second plurality of conductors embedded in said second adhesive such that portions of said second plurality of conductors protrude from said second adhesive;
said portions of said second plurality of conductors being soldered to said layer of aluminum by an alloy coating on said portions to form ohmic connections between said portions of said second plurality of conductors and said outer surface of second doped volume through laser-fired contacts to permit the electric current generated by said photovoltaic semiconductor apparatus to be conducted by said second plurality of conductors.

44. A method of making a photovoltaic semiconductor apparatus for use in forming a solar cell, the method comprising:
forming a first plurality of openings in a first passivation layer on a front side of a first doped volume of semiconductor material of a semiconductor wafer having first and second adjacent oppositely doped volumes of semiconductor material forming a heterojunction, said first plurality of openings defining corresponding unpassivated areas of said first front side that are
forming a first conductive anti-reflective coating on a first outer surface of said first passivation layer and on said corresponding unpassivated areas of said front side.

45. The method of claim 44 wherein forming said first plurality of openings comprises causing each opening of said first plurality of openings to have a width of about 50 micrometers to about 200 micrometers.

46. The method of claim 44 wherein forming said first plurality of openings in said first passivation layer comprises arranging said first plurality of openings in parallel lines across said first outer surface.

47. The method of claim 46 wherein forming said first plurality of openings comprises causing said parallel lines to be spaced apart by about 500 micrometers to about 5000 micrometers.

48. The method of claim 44 wherein forming said first plurality of openings in said first passivation layer comprises arranging said first plurality of openings in parallel lines connected by cross parallel lines to form a grid arrangement.

49. The method of claim 48 wherein said grid arrangement has meshes of approximately about 500 micrometers to about 5000 micrometers square.

50. The method of claim 44 wherein forming said first conductive anti-reflective coating comprises forming a first continuous conductive anti-reflective coating on said first outer surface and on said unpassivated areas of said front side surface.

51. The method of claim 44 wherein forming said first conductive anti-reflective conductive coating comprises causing said first conductive anti-reflective coating to have a thickness of about 70 nm to about 280 nm.

52. The method of claim 44 wherein forming said first conductive anti-reflective coating on said first outer surface and on said unpassivated areas of said front side surface comprises applying a material including at least one of InOx; SnOx, InSnOx; TiOx; and ZnOx to said first outer surface and said unpassivated areas of said front side surface.

53. The method of claim 44 wherein forming said first conductive anti-reflective coating comprises causing said first conductive anti-reflective coating to have a sheet resistivity of about 1 Ohm/Sq to about 30 Ohm/Sq.

54. The method of claim 44 further comprising forming said heterojunction by at least one of ion-implanting and thermal diffusion.

55. The method of claim 44 further comprising causing said first doped volume to have a sheet resistivity of 60 ohms per square to 150 ohms per square.

56. The method of claim 44 further comprising causing said first doped volume to have a sheet resistivity of 80 ohms per square to 150 ohms per square.

57. The method of claim 44 further comprising forming said first passivation layer.

58. The method of claim 57 wherein forming said first passivation layer comprises forming a layer of at least one of SiO₂, SiN₄ and SiC on said front side.

59. The method of claim 57 wherein forming said first passivation layer comprises causing said first passivation layer to have a thickness of about 10 nm to about 500 nm.

60. The method of claim 57 wherein forming said first passivation layer comprises causing said first passivation layer to have a thickness of about 10 nm to about 50 nm.

61. The method of claim 44 further comprising:
forming a second plurality of openings in a second passivation layer on a back side surface of said second doped volume of said semiconductor material, said second plurality of openings defining corresponding unpassivated areas on said back side surface; and
forming a second conductive anti-reflective coating on an outer surface of said second passivation layer and on said unpassivated areas of said second back side surface.

62. The method of claim 61 wherein forming said second plurality of openings comprises causing each of said second plurality of openings to have a width of about 50 micrometers to about 200 micrometers.

63. The method of claim 61 wherein forming said second plurality of openings in said second passivation layer comprises arranging said second plurality of openings in parallel lines across said back side surface.

64. The method of claim 63 wherein arranging said second plurality of openings in parallel lines comprises causing said parallel lines to be spaced apart by about 500 micrometers to about 5000 micrometers.

65. The method of claim 61 wherein forming said second plurality of openings in said second passivation layer comprises arranging said second plurality of openings in parallel lines connected by cross parallel lines to form a grid arrangement.

66. The method of claim 65 wherein arranging said second plurality of openings in parallel lines connected by cross parallel lines to form a grid arrangement comprises causing said grid arrangement to have meshes of approximately about 500 micrometers to about 5000 micrometers square.

67. The method of claim 61 wherein forming said second conductive anti-reflective coating comprises forming a second continuous conductive anti-reflective coating on said outer surface of said second passivation layer and on said unpassivated areas of said back side surface.

68. The method of claim 67 wherein forming said second conductive anti-reflective conductive coating comprises causing said coating to have a thickness of about 70 nm to about 500 nm.

69. The method of claim 61 wherein forming said second conductive anti-reflective coating comprises coating said outer surface of said second passivation layer and said unpassivated areas of said back side surface with a material including at least one of InOx; SnOx, InSnOx; TiOx; and ZnOx.

70. The method of claim 61 wherein forming said second conductive anti-reflective coating comprises causing said second conductive anti-reflective coating to have a sheet resistivity of about 1 Ohm/Sq to about 30 Ohm/Sq.

71. The method of claim 61 further comprising forming said second passivation layer.

72. The method of clam 69 wherein forming said second passivation layer comprises forming a layer of at least one of SiO₂, SiN₄ and SiC on said back side surface.

73. The method of claim 69 wherein forming said second passivation layer comprises causing said second passivation layer to have a thickness of about 10 nm to about 500 nm.

74. The method of claim 69 wherein forming said second passivation layer comprises causing said second passivation layer to have a thickness of about 10 nm to about 50 nm.

75. The method of claim 61 further comprising:
adhering an adhesive on an optically transparent electrically insulating film to said first conductive anti-reflective coating such that portions of an alloy coating on corresponding exposed portions of a first plurality of conductors embedded in said adhesive are disposed on said first conductive anti-reflective coating; and
heating said alloy coating while pressing said exposed portions against said first conductive anti-reflective coating to cause said alloy coating to solder said exposed portions of said first plurality of conductors to said first conductive anti-reflective coating to create ohmic connections between said first plurality of conductors and said first conductive anti-reflective coating.

76. The method of claim 75 further comprising:
adhering a second adhesive on a second electrically insulating film to said second conductive anti-reflective coating such that portions of a second alloy coating on corresponding exposed portions of a second plurality of conductors embedded in said second adhesive are disposed on said second anti-reflective conductive coating; and
heating said second alloy coating while pressing said exposed portions of said second plurality of conductors against said second conductive anti-reflective coating to cause said second alloy coating to solder said exposed portions of said second plurality of conductors to said second conductive anti-reflective coating to create ohmic connections between said second plurality of conductors and said second conductive anti-reflective coating.

77. The method of claim 44 further comprising:
forming a second conductive anti-reflective coating on a back side surface of a third doped volume on a side of said second doped volume opposite said semiconductor junction, said third doped volume having the same doping polarity as said second volume thereby forming an isotype junction and wherein said third doped volume has a doping concentration greater than a doping concentration of said second volume.

78. The method of claim 77 wherein forming said second conductive anti-reflective coating comprises forming a second continuous conductive anti-reflective coating on said back side surface of said third doped volume.

79. The method of claim 77 wherein forming said second conductive anti-reflective coating comprises causing said second conductive anti-reflective coating to have a thickness of about 70 nm to about 500 nm.

80. The method of claim 77 wherein forming said second conductive anti-reflective coating comprises coating said back side surface of said third doped volume with a material including at least one of InOx; SnOx, InSnOx; TiOx; and ZnOx.

81. The method of claim 77 wherein forming said second conductive anti-reflective coating comprises causing said second conductive anti-reflective coating to have a sheet resistivity of about 1 Ohm/Sq to about 30 Ohm/Sq.

82. The method of claim 44 further comprising:
adhering an adhesive on an optically transparent electrically insulating film to said first conductive anti-reflective coating such that portions of an alloy coating on corresponding exposed portions of a first plurality of conductors embedded in said adhesive are disposed on said first conductive anti-reflective coating; and
heating said alloy coating while pressing said exposed portions against said first conductive anti-reflective coating on said unpassivated areas to cause said alloy coating to solder said exposed portions of said first plurality of conductors to said conductive anti-reflective coating to create ohmic connections between said first plurality of conductors and said first conductive anti-reflective coating

83. The method of claim 82 further comprising:
adhering a second adhesive on a second electrically Insulating film to said second conductive anti-reflective coating such that portions of a second alloy coating on corresponding exposed portions of a second plurality of conductors embedded in said second adhesive are disposed on said second conductive anti-reflective coating; and
heating said second alloy coating while pressing said exposed portions of said second plurality of conductors against said second conductive anti-reflective coating to cause said second alloy coating to solder said exposed portions of said second plurality of conductors to said second conductive anti-reflective coating to create ohmic connections between said second plurality of conductors and said second conductive anti-reflective coating.

84. The method of claim 44 further comprising forming a second passivation layer on a back side surface of said second volume.

85. The method of claim 84 further comprising forming a layer of aluminum on said second passivation layer.

86. The method of claim 84 further comprising forming a plurality of laser-fired contacts in said layer of aluminum.

87. The method of claim 86 further comprising:
adhering an adhesive on an optically transparent electrically insulating film to said first conductive anti-reflective coating such that portions of an alloy coating on corresponding exposed portions of a first plurality of conductors embedded in said adhesive are disposed on said front side; and
heating said alloy coating while pressing said exposed portions against said first conductive anti-reflective coating on said unpassivated areas to cause said alloy coating to solder said exposed portions of said first plurality of conductors to said conductive anti-reflective coating to create ohmic connections between said first plurality of conductors and said first conductive anti-reflective coating.

88. The method of claim 87 further comprising:
adhering a second adhesive on a second electrically insulating film to said layer of aluminum such that a second alloy coating on corresponding exposed portions of a second plurality of conductors embedded in said second adhesive are disposed on said layer of aluminum; and
heating said second alloy coating while pressing said exposed portions of said second plurality of conductors against said layer of aluminum to cause said second alloy coating to solder said exposed portions of said second plurality of conductors to said layer of aluminum to create ohmic connections between said second plurality of conductors and said layer of aluminum to permit current to flow between said second plurality of conductors and said second doped volume through said laser-fired contacts and said layer of aluminum.

89. A photovoltaic semiconductor apparatus for use in forming a solar cell, the apparatus comprising:
first and second adjacent oppositely doped volumes of semiconductor material forming a semiconductor heterojunction, said first doped volume acting as an emitter having a front side for receiving light;
a first passivation layer of material on said front side, said first passivation layer having a first outer surface and a plurality of openings therethrough defining corresponding unpassivated areas of said front side that are unpassivated by said first passivation layer;
a dielectric anti-reflective coating on said first outer surface of said passivation layer, said openings being void of said dielectric anti-reflective coating; and
a first conductive anti-reflective coating on said dielectric anti-reflective coating and on said corresponding unpassivated areas of said front side.

90. The apparatus of claim 89 wherein said semiconductor heterojunction is at least one of an ion-implanted heterojunction and a thermally diffused heterojunction.

91. The apparatus of claim 89 wherein said first doped volume has a sheet resistivity of about 60 ohms per square to about 150 ohms per square.

92. The apparatus of claim 89 wherein said first doped volume has a sheet resistivity of about 80 ohms per square to about 150 ohms per square.

93. The apparatus of claim 89 wherein said first passivation layer is comprised of at least one of SiO₂, SiN₄ and SiC.

94. The apparatus of claim 89 wherein said first passivation layer has a thickness of about 10 nm to about 200 nm.

95. The apparatus of claim 94 wherein said first passivation layer has a thickness of about 10 nm to about 50 nm.

96. The apparatus of claim 89 wherein said openings in said first passivation layer have a width of about 50 micrometers to about 200 micrometers.

97. The apparatus of claim 89 wherein said openings in said first passivation layer have an elongate shape having a length of between about 0.5 mm and about 4 mm and a width of between about 0.1 mm and about 1 mm.

98. The apparatus of claim 97 wherein said openings may be spaced apart by about 1-mm to about 6 mm

99. The apparatus of claim 89 wherein said openings in said first passivation layer are arranged in parallel lines across said first outer surface.

100. The apparatus of claim 99 wherein said parallel lines are spaced apart by about 500 micrometers to about 5000 micrometers.

101. The apparatus of claim 99 wherein said parallel lines are connected by cross parallel lines to form a grid arrangement.

102. The apparatus of claim 101 wherein said grid arrangement has meshes of about 500 micrometers to about 5000 micrometers square.

103. The apparatus of claim 89 wherein said dielectric anti-reflective coating has a thickness of about 70 to about 100 nm.

104. The apparatus of claim 89 wherein said dielectric anti-reflective coating is comprised of silicon nitride.

105. The apparatus of claim 89 wherein said dielectric anti-reflective coating has an index of refraction of between about 2.0 and about 2.5.

106. The apparatus of claim 89 wherein said first conductive anti-reflective coating comprises conductive oxides of at least one of Indium, Tin, Titanium and Zinc.

107. The apparatus of claim 89 wherein said first conductive anti-reflective coating comprises a fluoride-doped oxide of at least one of Indium and Tin.

108. The apparatus of claim 89 wherein said first conductive anti-reflective coating has a thickness of between about 70 to about 100 nanometers.

109. The apparatus of claim 89 wherein said first conductive anti-reflective coating has a refractive index of between about 1.7 and about 1.9.

110. The apparatus of claim 89 wherein said dielectric anti-reflective coating has a refractive index of between about 2.0 and about 2.5 and said first conductive anti-reflective coating has a refractive index of between about 1.7 and about 1.9.

111. A method of forming a photovoltaic semiconductor apparatus for use in forming a solar cell, the method comprising:
forming a plurality of openings in a dielectric anti-reflective coating and a first passivation layer on a front side of a first doped volume of semiconductor material of a semiconductor wafer having first and second adjacent oppositely doped volumes of semiconductor material forming a heterojunction, to form passivated dielectric-coated areas on said front side and exposed portions of said front side of said first doped volume therebetween; and
forming a first conductive anti-reflective coating on said passivated dielectric coated areas and said exposed areas of said front side surface.

112. The method of claim 111 wherein forming said plurality of openings comprises using a first material removal process to remove areas of said dielectric anti-reflective coating until residual portions of the dielectric anti-reflective coating remain such that portions of a surface of said first passivation layer are almost exposed and using a second process to remove said residual portions and to remove corresponding portions of said first passivation layer to create said exposed areas of said front side surface.

113. The method of claim 112 wherein said first process involves at least one of laser ablation and selective plasma etching and wherein said second process involves wet chemical etching.

114. The method of claim 113 wherein wet chemical etching involves wet chemical etching using fluoric acid.

115. The method of claim 114 further comprising causing wet chemical etching to occur until said dielectric anti-reflective layer has a thickness between about 70 nanometers to about 100 nanometers.
